(19) United States
(12) Patent Application Publication
(10) Pub. No.: US 2025/0314710 A1
(43) Pub. Date: Oct. 9, 2025

(54) ESTIMATING BATTERY STATE OF HEALTH AND STATE OF CHARGE

(71) Applicant: Iontra Inc, Centennial, CO (US)

(72) Inventors: Zhong WANG, Sugar Land, TX (US); Ruzhou YANG, Hayward, TX (US); Manoj K. KOUL, Allen, TX (US)

(21) Appl. No.: 19/171,048

(22) Filed: Apr. 4, 2025

Related U.S. Application Data
(60) Provisional application No. 63/575,395, filed on Apr. 5, 2024.

(51) Int. Cl. G01R 31/392; G01R 31/367; G01R 31/374; G01R 31/3835; G01R 31/389; G01R 31/396; H01M 10/42

(52) U.S. Cl. CPC G01R 31/392; G01R 31/367; G01R 31/374; G01R 31/3835; G01R 31/389; G01R 31/396; H01M 10/4285

(57) ABSTRACT

A method of generating a State of Health (SOH) estimate for a battery is disclosed. The method may include charging a battery to a reference point and obtaining a battery cell temperature at the reference point, obtaining an instantaneous impedance of the battery cell based on the battery cell's response to an applied probing waveform, and obtaining a SOH estimate based on the battery cell temperature and the instantaneous impedance. Methods of generating a State of Charge (SOC) estimate for a battery and of determining an amount of remaining device usage are also disclosed.

### CROSS-REFERENCE TO RELATED APPLICATION

This application claims priority to U.S. Provisional Patent Application No. 63/575,395, filed Apr. 5, 2024, entitled “ESTIMATING BATTERY STATE OF HEALTH AND STATE OF CHARGE,” the entire disclosure of which is hereby incorporated by reference, for all purposes, as if fully set forth herein.

### TECHNICAL FIELD

Embodiments of the present invention generally relate to systems and methods for predicting the state of health of a lithium-ion battery and dynamically adjusting a charging profile based at least in part on the predicted state of health.

### BACKGROUND AND INTRODUCTION

Rechargeable batteries are widely used in electrically powered devices such as tools, lawn equipment, mobile computing devices, communication devices, portable electronic devices, household appliances, and electrical vehicles (EVs). Rechargeable batteries are limited by finite battery capacity and must be recharged upon depletion. Because the powered device must often be tethered to an outlet or a charging station during the recharging period, and in some cases may not be used during the recharging period, recharging a battery may be inconvenient to users. In some cases, the recharging period for a battery can last for hours.

High current charging methods have been developed to accelerate charge times. These fast charge systems rely on costly high-power electronics to deliver the required levels of charge current. Moreover, fast charging can lead to battery degradation and reduced battery performance over time. To preserve battery health, high current delivery to the battery is limited at some fixed percentage of charge during a charging cycle and the remainder of the battery charging up to 100% occurs at a slower rate. Thus, existing fast charge methods and systems are complex, inexact, and may still have potential to damage the battery.

It is with these observations in mind, among others, that aspects of the present disclosure were conceived.

### SUMMARY

Aspects of the present disclosure include a method of generating a State of Health (SOH) estimate for a battery. The method may include charging a battery to a reference point and obtaining a battery cell temperature at the reference point. The method may further include obtaining an instantaneous impedance of the battery cell based on the battery cell's response to an applied probing waveform and obtaining a SOH estimate based on the battery cell temperature and the instantaneous impedance.

Additional aspects of the present disclosure relate to methods of generating a State of Charge (SOC) estimate for a battery. The method may include receiving, at an initial SOC estimate module, a first time step voltage measurement, a first time step current measurement, and an equivalent circuit model (ECM). Using the first time step voltage measurement, the first time step current measurement, and the ECM, an initial SOC estimation process may be performed to obtain an initial SOC estimate. The initial SOC estimate, along with a second time step voltage measurement, may be provided to an initial potential adjustment module. Using the initial SOC estimate and the second time step voltage measurement, an initial potential adjustment process may be performed to obtain at least one state estimate, wherein the at least one state estimate includes an updated initial SOC estimate. The at least one state estimate, a second time step current measurement, and a third time step voltage measurement may be provided to an extended Kalman filter (EKF) module. Using the at least one state estimate, the second time step current measurement, and the third time step voltage measurement, an EKF process may be performed to obtain a current time step SOC estimate.

Additional aspects of the present disclosure relate to methods for determining an amount of remaining device usage. The method may include obtaining a SOH estimate for a battery within a device, obtaining a SOC estimate for the battery within the device, and obtaining an amount of energy discharge required to use the device. The method may further include determining the amount of remaining device use available given the battery's SOH, SOC, and amount of energy discharge required.

### BRIEF DESCRIPTION OF THE DRAWINGS

The various objects, features, and advantages of the present disclosure set forth herein will be apparent from the following description of embodiments of those inventive concepts, as illustrated in the accompanying drawings. Drawings presented herein are not necessarily to scale and may be representative of various features of an embodiment, with emphasis being placed on illustrating the principles and other aspects of the inventive concepts. Also, in the drawings the like reference characters may refer to the same parts or similar throughout the different views. It is intended that the embodiments and figures disclosed herein are considered illustrative rather than limiting.

FIG. 1 is a voltage versus time graph illustrating a direct current internal resistance (DCIR) and an instantaneous impedance, in accordance with embodiments herein.

FIGS. 2A and 2B are plots of instantaneous impedance versus State of Charge (SOC) percentage and DCIR versus SOC percentage, respectively, in accordance with embodiments herein.

FIGS. 3A and 3B are current waveform and voltage waveform graphs, respectively, associated with a probing waveform, in accordance with embodiments herein.

FIG. 4 is a graph of instantaneous impedance as a function of SOC and cell age, in accordance with embodiments herein.

FIG. 5 is a graph of instantaneous impedance as a function of remaining capacity, in accordance with embodiments herein.

FIG. 6 is a graph of instantaneous impedance as a function of number of remaining cycles, in accordance with embodiments herein.

FIG. 7 is a graph of instantaneous impedance as a function of SOC and temperature, in accordance with embodiments herein.

FIG. 8 is a graph of instantaneous impedance as a function of temperature, in accordance with embodiments herein.

FIG. 9 is a block diagram of a method for estimating State of Health (SOH) and/or End of Life (EOL) for a battery cell, in accordance with embodiments herein.

FIG. 10 is a three-dimensional plot showing relationships between instantaneous impedance, temperature, and remaining capacity, in accordance with embodiments herein.

FIG. 11 is a graph comparing predicted SOH values versus true SOH values, in accordance with embodiments herein.

FIG. 12 is a chart showing absolute error between predicted SOH values and true SOH values as a function of temperature set point, in accordance with embodiments herein.

FIG. 13 is an equivalent circuit model used in a SOC estimation algorithm, in accordance with embodiments herein.

FIG. 14A is a current versus time graph showing an example probing signal, in accordance with embodiments herein.

FIG. 14B is a comparison of experimental and predicted voltage data, in accordance with embodiments herein.

FIGS. 15A-15F show plots of Open Circuit Voltage (OCV), resistance R0, time constant τ₁, resistance R1, time constant τ₂, and resistance R2 as a function of SOC, respectively, in accordance with embodiments herein.

FIGS. 16A and 16B illustrate comparisons between experimental and identified data for current versus SOC and voltage versus SOC, respectively, respectively, in accordance with embodiments herein.

FIG. 17 is a block diagram of a SOC estimation algorithm, in accordance with embodiments herein.

FIG. 18 is a plot showing SOC error versus actual SOC, in accordance with embodiments herein.

FIG. 19 is a plot showing SOC error versus actual SOC for a plurality of initial potential values, in accordance with embodiments herein.

FIG. 20 is a plot of root mean square (RMS) error versus initial potential values, in accordance with embodiments herein.

FIG. 21 is a block diagram of an algorithm for updating state values using an extended Kalman filter (EKF), in accordance with embodiments herein.

FIG. 22 is a plot showing SOC prediction error versus time, in accordance with embodiments herein.

FIG. 23 is a block diagram of an example computer system having various functional modules, in accordance with embodiments herein.

### DETAILED DESCRIPTION

Battery longevity and charging speed can be greatly improved by using charge signals that are optimized for a specific type or condition of a battery. Optimizing a charge signal for this purpose may require inputs and measurements from the battery and/or model-based predictions about real-time conditions at the battery. Parameters of the charge signal may be selected based on this information to increase charge speed and/or reduce detrimental processes (e.g., plating and dendrite formation) to increase battery longevity. However, to achieve these beneficial results, highly accurate measurements and reliable predictions of a variety of battery cell characteristics should be obtained. Inexact measurements or predictions may result in reduced efficiency charging and/or damage to the battery being charged.

One battery cell characteristic that is important in determining an appropriate charging signal is battery state of health (SOH). State of health as used herein is defined as the percentage of remaining capacity over the rated capacity. The SOH may be quantified as a percentage between 0-100%. For example, a battery may have a rated capacity of 3,000 mAh. When the battery is new, its remaining capacity is the same as its rated capacity, therefore SOH is 100%. However, after some use, the remaining capacity may drop to 2700 mAh. In this case, the SOH would be 90% as calculated using Equation 1:

$$SOH \% = ( \frac{remaining capacity}{rated capacity} ) \times 100. \qquad Eq . 1$$

As capacity decreases over the life of a battery, changes to the structure or materials within the battery may occur. To minimize damage to the battery, a battery charging profile may be generated or selected to account for these material changes. The SOH metric may correlate with the physical changes within the battery and may thus be used in selecting or generating a battery charging profile that is appropriate for the battery's condition and that prolongs battery life and/or reduces the rate of degradation and/or the rate at which capacity is decreasing.

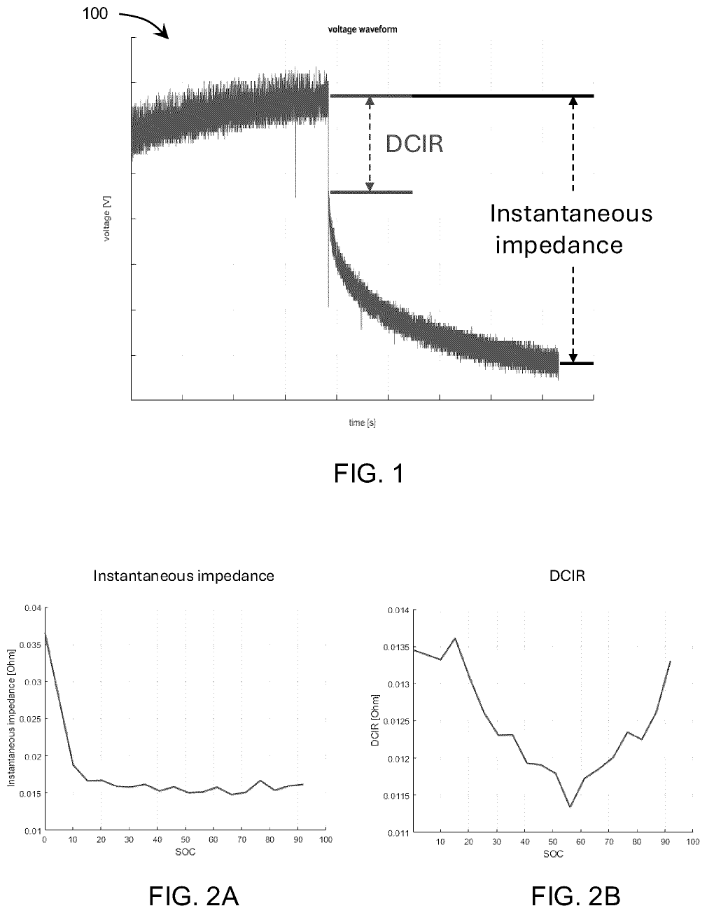

Another way of determining the SOH of a lithium based cell is by measuring its internal impedance. Some SOH estimation methods may determine impedance by relying entirely on Direct Current Internal Resistance (DCIR) measurements. However, in the SOH estimation method described herein, an instantaneous impedance (represented as variable Z) is used. The instantaneous impedance Z differs from the DCIR approach in that it includes both an internal DC resistance (which can be calculated from DCIR) and a transient complex impedance. FIG. 1 illustrates a plot 100 that shows voltage waveform sections used for DCIR-only in contrast to the instantaneous impedance used herein. The DCIR method typically uses the section of direct drop to calculate internal DC resistance. The instantaneous impedance is calculated from the voltage change including both direct drop as well as the subsequent relaxation.

FIGS. 2A and 2B show plots of instantaneous impedance and DCIR, respectively, over a range of state of charge (SOC) for the same example lithium metal cell. It can be seen that the instantaneous impedance has a larger dynamic range over the SOC range, representing a more comprehensive state of health. In contrast, the DCIR has less variation over the same range of SOC, representing only that the change in resistance may be due to electronic resistances.

In general, internal impedance increases with increasing degradation of the battery cell. Internal impedance is represented by an “instantaneous impedance” value, Z, derived using probing current and voltage waveforms in a time domain. In some embodiments, a time-domain limited secondary waveform or pulse may be used as a probing signal. The duration of the pulse may be selected from a range (e.g., a range from 1-100 seconds). In some embodiments, a unipolar pulse waveform may be used as a probing waveform. The probing pulse may be applied to the battery using a battery charging circuit; however, other configurations are possible. For example, if during regular use of a device powered by the battery, the device load creates a current and voltage waveform similar to, or within tolerance of, a probing waveform, the resulting data may be used to determine the instantaneous impedance without being connected to a charger or specifically delivering a probing pulse. In some embodiments, the device connected to and powered by the battery may include circuitry configured to specifically apply a probing signal to the battery. Over the course of a single charge and/or discharge cycle, probing signals from one or more of the sources (e.g., probing by a charger, probing by application of load on the battery during device use, or probing initiated by circuitry on the device) may be applied to measure instantaneous impedance and/or determine other parameters related to characterization of the SOC and/or State of Health (SOH) of the battery.

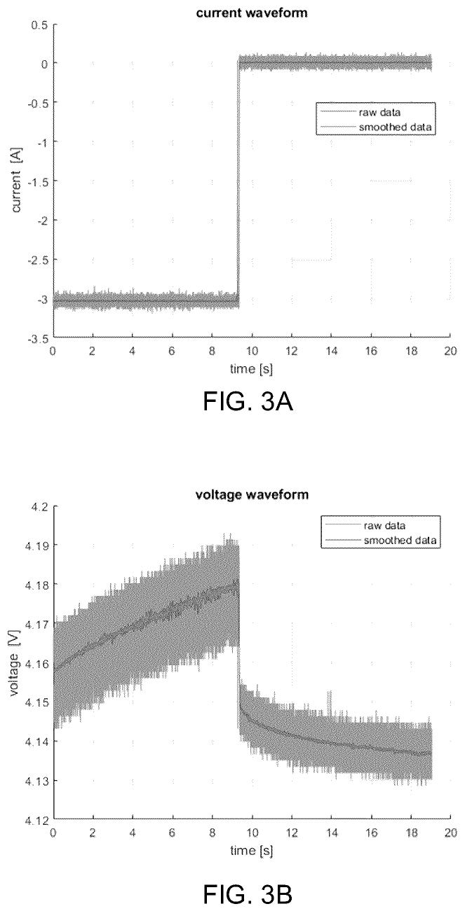

FIGS. 3A and 3B illustrate current and voltage, respectively, of an example unipolar pulse waveform used to calculate instantaneous impedance, Z. The calculation is performed using Equation 2, where Vₛₘₒₒₜₕ and Iₛₘₒₒₜₕ are smoothed voltage and current, respectively, as illustrated in the reduced variation lines of FIGS. 3A and 3B:

$$Z = \frac{Δ V}{Δ I} = \frac{max ( {V}_{smooth} ) - min ( {V}_{smooth} )}{max ( {I}_{smooth} ) - min ( {I}_{smooth} )} . \qquad Eq . 2$$

In some embodiments, data from the entire unipolar pulse waveform may be used to calculate the instantaneous impedance, Z. Alternatively, in some embodiments, data from a portion less than the entirety of the unipolar pulse waveform may be used. For example, data from one or more segments of the unipolar pulse waveform may be used to calculate the instantaneous impedance, Z.

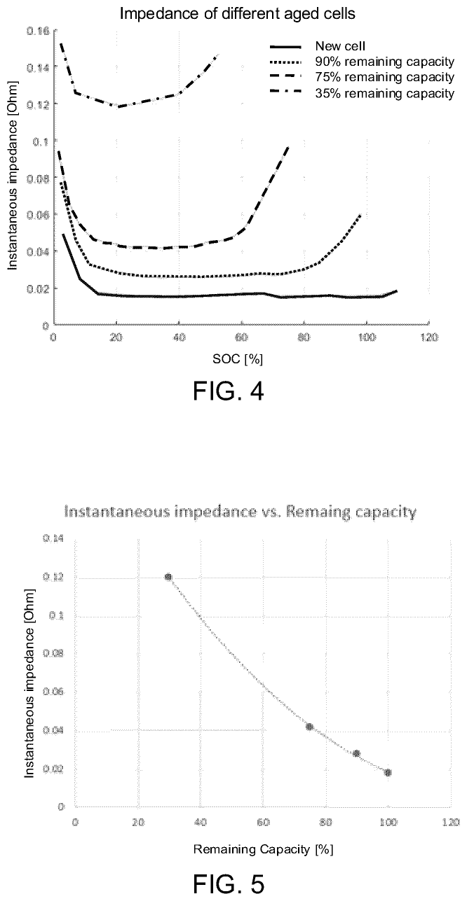

Correlating the instantaneous impedance, Z, to an SOH value may be performed using models (e.g., constrained neural network models, statistical models, etc.), tables (e.g., look-up tables having two or more dimensions), equations (e.g., one or more equation describing or approximating a data set, polynomial equations, equation of best fit, etc.), or other data sets that include, or are based on, results of prior battery testing. This battery testing may be referred to herein as “cell characterization,” may occur “offline” in a testing setup rather than during battery use, and may include in-depth analysis of cell materials, physical properties, and responses to various charge, discharge, and/or probing signal profiles. In some embodiments, testing of multiple battery cells may account for various battery temperatures, states of charge, and/or cell ages (e.g., as quantified by number of charge/discharge cycles experienced, amount of expected remaining capacity, etc.). FIG. 4 illustrates test results of four battery cells of different known ages (i.e., new, 90% capacity remaining, 75% capacity remaining, 35% capacity remaining) where impedance was measured over SOC ranging between approximately 0% to approximately 100% at a constant temperature of 25° C. FIG. 5 shows the resulting correlation between instantaneous impedance and remaining capacity. In some embodiments, this correlation may be used to develop an equation, model, or look-up table that can be used to determine remaining capacity based on instantaneous impedance. The remaining capacity may then be used to calculate or estimate the battery's SOH as discussed above with respect to Equation 1.

In addition to correlating instantaneous impedance to remaining capacity, testing may be performed during the cell characterization process to facilitate the mapping of instantaneous impedance to a charge cycle number and to a number of remaining cycles. A battery's charge cycle number may be used to select or generate a charging profile for the battery and may be used to estimate the number of charge/discharge cycles remaining before the battery's End of Life (“EOL”) is reached. The EOL value as used herein may refer to a minimum remaining capacity threshold. For example, a battery may reach EOL when it has reached 70% of its rated capacity remaining. While an EOL of 70% remaining capacity is given here as an example, the selected EOL value may vary and, in some embodiments, may be selected based on the type of device the battery is powering. For example, selected EOL values for batteries powering electric vehicles, medical devices, and smart phones, for example, may be different.

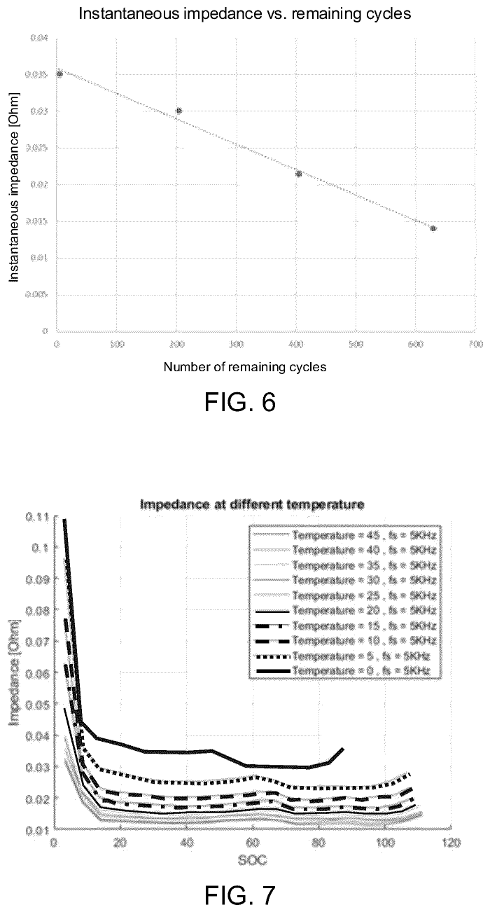

FIG. 6 illustrates a correlation between instantaneous impedance and number of cycles remaining for a battery. In some embodiments, an equation, look-up table, or other model may be developed for use in determining or estimating a number of cycles remaining for a battery based on an instantaneous impedance input. Notably, the correlation between instantaneous impedance and number of cycles remaining may vary based on the specific charge profile being used.

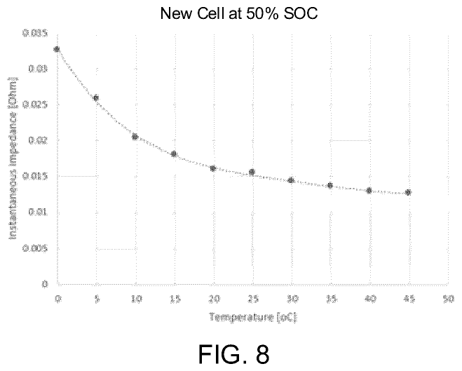

The internal impedance of lithium-ion batteries is sensitive to temperature; therefore, temperature effects may be considered in the process of estimating SOH, EOL, remaining cycles, and other metrics using instantaneous impedance, in various embodiments. FIG. 7 shows instantaneous impedance as a function of state of charge at a range of temperatures. It can be seen from the graph in FIG. 7, and more explicitly from the impedance vs. temperature graph of FIG. 8, that impedance decreases with increasing temperature.

Because cells of different ages have different capacities, using SOC as a reference point to make impedance measurements does not guarantee that the cells are measured in a similar condition. Instead or additionally, the open-circuit voltage (“OCV”) value may be used as a reference point for instantaneous impedance measurement. In some embodiments, a value between approximately 20% of the OCV value and approximately 80% of the nominal voltage range for a battery cell may be selected as a reference point. A look-up table may then be built by taking temperature and instantaneous impedance as inputs and performing interpolation.

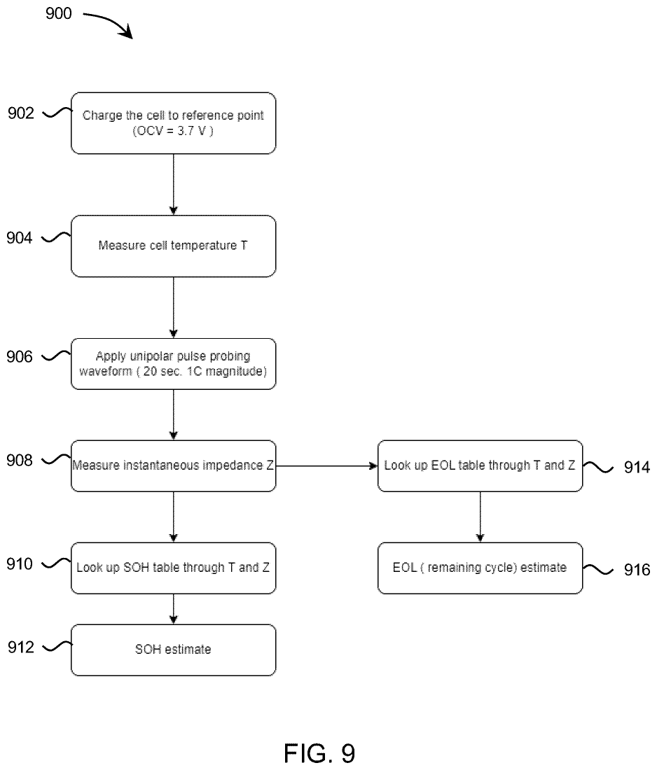

Referring to FIG. 9, a block diagram is shown that describes steps of a method 900 for estimating SOH for a battery cell. At Step 902, a battery cell is charged to a reference point. In some embodiments, the reference point may be an OCV value (e.g., 3.7V). At Step 904 a cell temperature, T, is obtained. The temperature T may be obtained by direct measurement or through the use of a cell temperature model. As discussed above, many battery cell performance metrics are dependent on cell temperature and thus, obtaining an accurate temperature measurement may enhance obtaining accurate correlated metrics. At Step 906, a probing waveform is applied to the battery cell. In some embodiments, the probing waveform may be a unipolar pulse probing waveform having a specified duration and charge rate magnitude (e.g., duration ranging from approximately 1 second to approximately 10 minutes and charge rate ranging from 0.1 C-5 C or higher, depending on the maximum charge rate of the battery cell); however, other types of probing waves, durations, and charge rate magnitudes may be selected depending on the battery cell, temperature, or other variables. In one specific example, a 20 second 1 C unipolar pulse is applied.

Using data obtained while applying the probing waveform of Step 906, an instantaneous impedance, Z, is obtained at Step 908. At Step 910, the measured cell temperature and instantaneous impedance may be used as inputs to a look-up table that correlates temperature, instantaneous impedance, and SOH. Using data in the SOH look-up table, a SOH estimate is obtained at Step 912. At Step 914, the measured cell temperature and instantaneous impedance may be used as inputs to a look-up table that correlates temperature, instantaneous impedance, and EOL. Using data in the EOL look-up table, an EOL estimate (e.g., in terms of number of remaining cycles, percent of rated capacity remaining, etc.) is obtained at Step 916.

In addition or as an alternative to determining an EOL estimate, an amount of available use time of the battery before depletion may be determined using one or more of the SOC estimate, the SOH estimate, and an instantaneous and/or average energy discharge required for an application. This information may be provided to a user of a product (e.g., by display in a user interface, display in a digital gauge, or otherwise) powered by the battery so that the user can determine if sufficient capacity remains in the battery to complete a task or if recharging should be performed. For example, a user may see that only 15 minutes of use time remains on their battery-powered tool before recharging is needed and may determine that this is a sufficient amount of use time for completing a project before recharging. In some embodiments where the demands of a specific task or application performed by a device are known, the number of remaining tasks that can be completed based on the battery's SOC and/or SOH may be provided. For instance, in a battery-powered nail gun, the instantaneous and/or average energy discharge to shoot a nail may be known. This information, along with battery SOC and/or SOH may be used to determine how many nails may be placed with the nail gun given the battery's SOC and/or SOH before recharging is needed and may be provided to a user via a display, audio cue, haptic feedback, or other on-board or peripheral user interface.

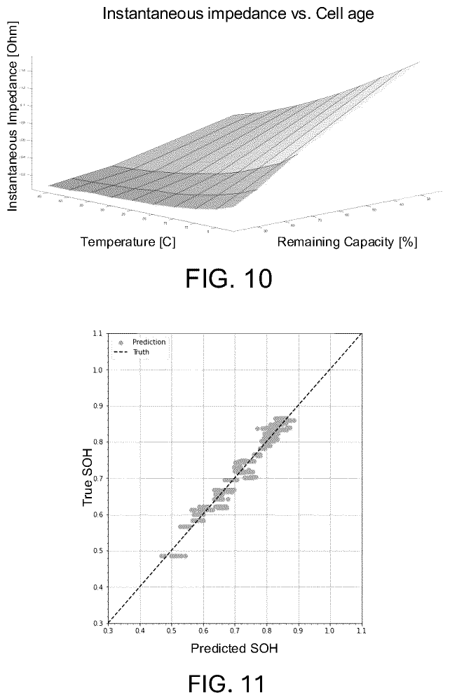

FIG. 10 shows an example plot with data correlating temperature, instantaneous impedance, and remaining capacity. Plots similar to this may be used as look-up tables similar to those discussed in Steps 914 and 916 of the method described with respect to FIG. 9.

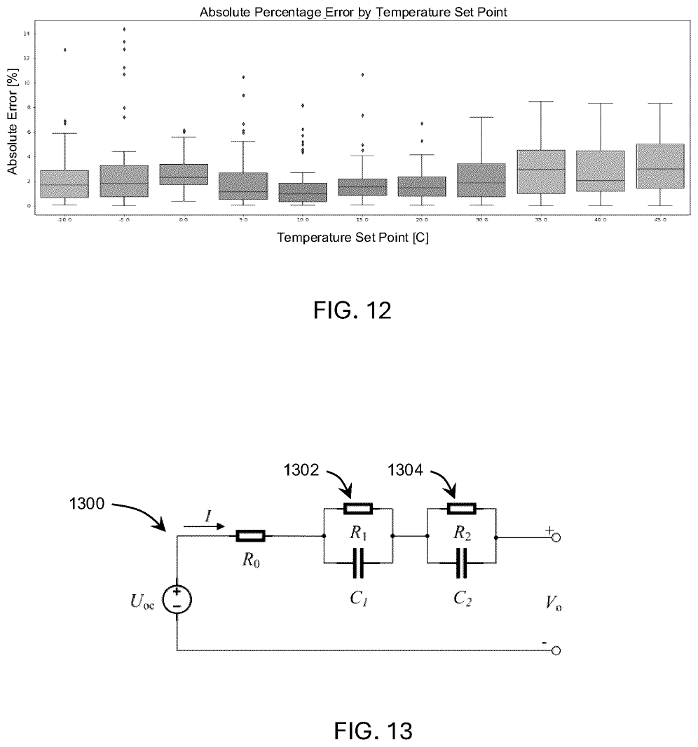

To confirm validity of the methods described herein to generate an accurate SOH estimate, SOH measurements were performed for comparison. Temperature ranges were selected between approximately −10° C. and approximately 45° C. and 16 battery cells were used for data collection. FIG. 11 shows a plot comparing SOH predictions to the true (i.e., measured) SOH values. FIG. 12 shows absolute percentage error between the SOH predictions and true SOH for each temperature tested. The maximum absolute percentage of error across all cells and temperatures was below 5%. This result validates the processes and algorithms described herein for generating SOH estimates or predictions.

In addition to estimating SOH and EOL, a State of Charge (SOC) may be estimated or predicted using an adaptive, dual-stage estimator to provide improved accuracy. In the first stage, an Extended Kalman Filter (EKF) may be applied to determine initial states for simplified cell dynamics (e.g., initial potentials, initial SOC). When the EKF SOC estimate converges, an optional second step of the algorithm may begin. In the second step, a coulomb counting method may be applied.

In some embodiments, the EKF is a model-based state estimator, where the model denotes the mathematical structure of the cell dynamics and may be understood as an equivalent circuit model. FIG. 13 shows an equivalent circuit model (ECM) 1300 which may be used to represent the EKF state estimator described herein. The model 1300 is a circuit that includes an open circuit voltage (OCV) U_{oc}, a resistance R₀, and two RC units 1302, 1304 arranged in series. Rᵢ and Cᵢ, where i=1,2 for RC units 1302 and 1304 respectively, represent a resistance and capacitance for the RC units. The output terminal voltage of the cell is represented as voltage Vₒ. In some embodiments, this model has been simplified to facilitate implementation of the EKF while maintaining the physical current-voltage dynamics.

The dynamics of the ECM may be expressed in three discrete state equations. Equation 3 describes SOC accumulation. Equations 4A and 4B describe evolution of potential over the RC units 1302, 1304 respectively. Equation 5 describes the output terminal voltage for the current-input-voltage-output relationships. The subscript k is the k^{th} step in discrete domain, I is the current input, V is the terminal voltage, Q_{cell} denotes the cell capacity, Tₛ is the discrete time step, and Uᵢ, τᵢ for i=1,2 are the potentials and the time constants over the corresponding RC units, respectively, where τᵢ=Rᵢ/Cᵢ.

$${SOC}_{k + 1} = {SOC}_{k} + \frac{{T}_{s}}{{Q}_{cell}} {I}_{k} \qquad Eq . 3$$

$${U}_{1 , k + 1} = {e}^{- \frac{{T}_{s}}{{τ}_{1}}} {U}_{1 , k} + ( 1 - {e}^{- \frac{{T}_{s}}{{τ}_{1}}} ) {R}_{1} {I}_{k} \qquad Eq . 4 A$$

$${U}_{2 , k + 1} = {e}^{- \frac{{T}_{s}}{{τ}_{2}}} {U}_{2 , k} + ( 1 - {e}^{- \frac{{T}_{s}}{{τ}_{2}}} ) {R}_{2} {I}_{k} \qquad Eq . 4 B$$

$${V}_{k + 1} = {OCV}_{k + 1} + {R}_{0} {I}_{k + 1} + {U}_{1 , k + 1} + {U}_{2 , k + 1} \qquad Eq . 5$$

These linear-formed dynamics may be inherently nonlinear in the states due to the fact that all ECM parameters (OCV, R0, R1, R2, τ₁, τ₂) are variables with respect to SOC, cell temperatures, and cell ages, thereby causing the ECM parameters to change at different charge levels and cell conditions. Thus, an ECM parameter look-up table along the dimensions of SOC, cell temperature, and cell age may be constructed prior to the implementation of the EKF algorithm. In particular, the ECM parameters in Equations 3-5 may be identified by charging a battery cell using unipolar current waveforms at selected SOC values and then adjusting the values so that the calculated terminal voltage in Equation 5 approximates the measured value. This tuning process may occur offline (e.g., through the use of testing data) rather than during real-time charging and discharging of a battery cell during use in a product. Equations are used throughout this discussion to relate ECM parameters to various outputs (e.g., SOC accumulation, first and second potentials, and terminal voltage). One or more of the equations may be constructed as matrices and/or look-up tables in a computer system or may be otherwise approximated to conserve computational time and resources.

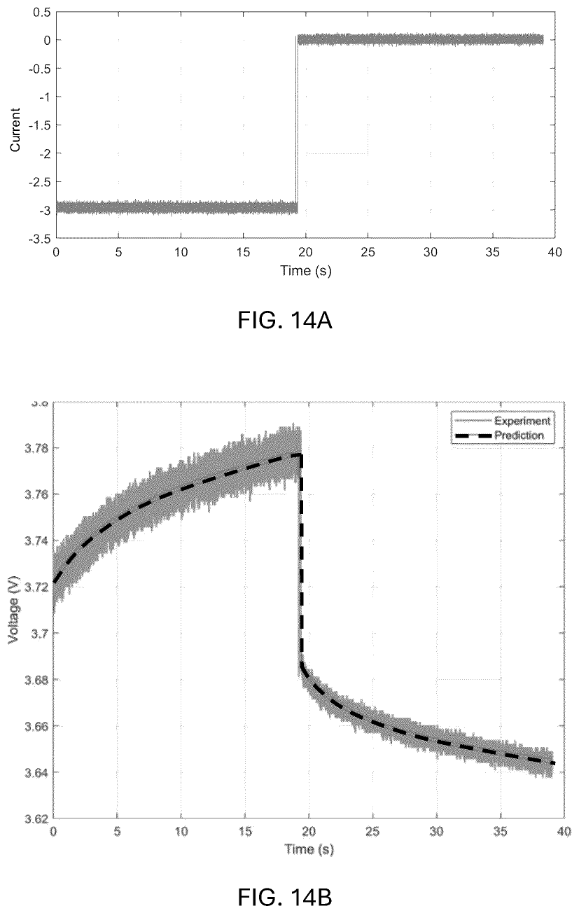

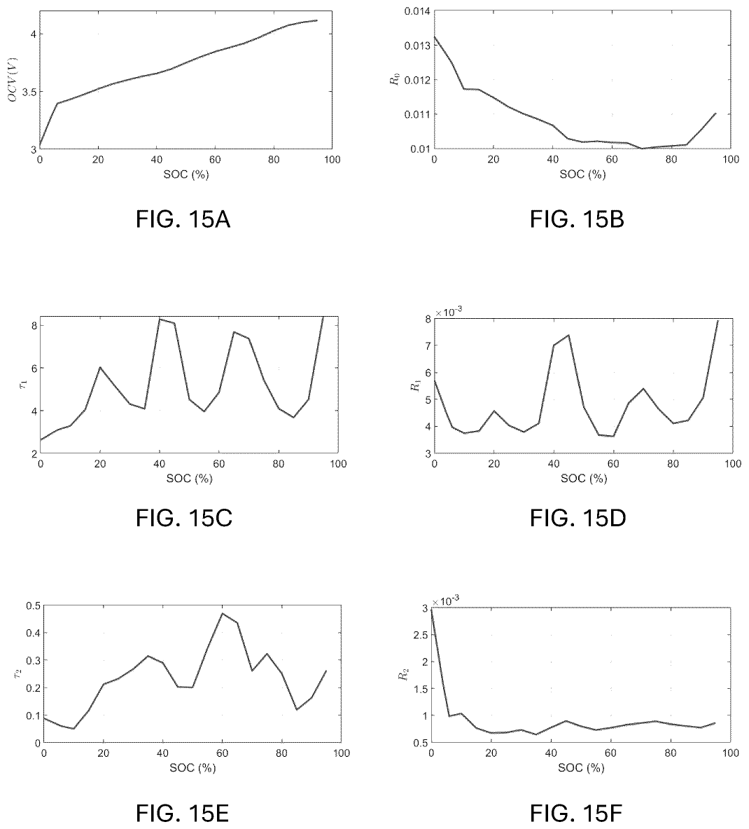

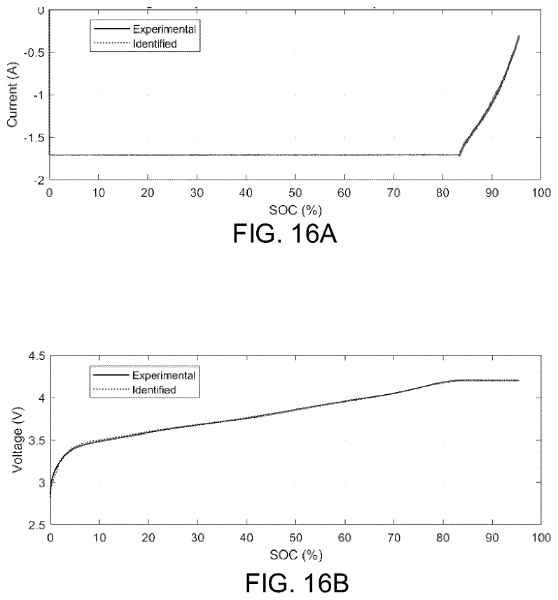

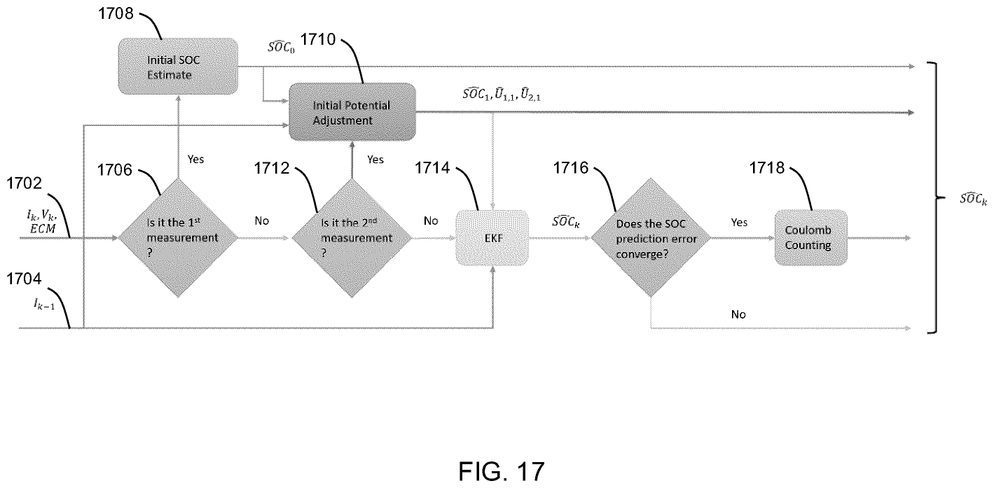

FIG. 14A shows a voltage versus time graph of one example of a unipolar current waveform. Such a waveform may be used for SOC ECM identification. FIG. 14B illustrates an identification result for one SOC where the “experiment” data represents the measured terminal voltage under a unipolar charging waveform (e.g., a waveform like the waveform of FIG. 14A) at a selected SOC value and the “prediction” data represents the voltage calculated using the adjusted ECM parameters. FIGS. 15A-F illustrate variables OCV, R0, τ₁, R1, τ₂, and R2, respectively, as a function of SOC % for a single temperature (e.g., 25° C.). FIGS. 15A-F illustrate that all of the ECM parameters are represented by nonlinear functions along the SOC range. The ECM parameters may be validated by performing a constant current constant voltage (CCCV) test where calculated (e.g., identified) terminal voltage and measured (e.g., experimental) terminal voltages are compared. Such a comparison is illustrated in the current versus SOC and voltage versus SOC plots of FIGS. 16A and 16B, respectively.

FIG. 17 is a block diagram showing steps of a method for performing an EKF-based SOC estimation. Inputs 1702 to the SOC estimation process include feedback signals that provide current step current Iₖ and current step voltage Vₖ measurement information and an ECM parameter look-up table as discussed above. Input 1704 to the SOC estimation process includes prior step current Iₖ₋₁. At least a portion of the inputs 1702 (e.g., current step voltage Vₖ) is evaluated at block 1706 to determine whether the measurement is the first received measurement. If yes, the first current step voltage measurement information is provided to the initial SOC estimation block 1708. The initial SOC estimation block 1708 calculates and outputs an initial SOC value [symbol] .

The initial SOC value [symbol] is intended to provide a rough estimation of SOC to serve as a starting point for following estimation steps that will provide more accurate estimations. The initial SOC value should be close enough to a ground truth SOC value where charging or discharging begins. To obtain the initial SOC value, initial current input I₀, initial voltage measurement V₀ and the ECM parameter look-up table are provided to the initial SOC estimation module 1708. These inputs are used to calculate an initial OCV estimate [symbol] according to Equation 6 below:

$$= {V}_{0} - {I}_{0} {\overline{R}}_{0} - {\hat{U}}_{0} . \qquad Eq . 6$$

In Equation 6, [symbol] is the estimated OCV at the initial time step, R̅₀ is the mean value of R₀ along the SOC in the ECM parameter look-up table under the current cell temperature and current cell age. The estimate of the summation of the initial potentials over the two RC-units is represented as Û₀. The initial potential estimate Û₀ may be important in obtaining an accurate estimate of the initial SOC because the initial potential variable may be particularly sensitive to low temperature conditions and cell age. Therefore, a look-up table with dimensions of cell temperature and cell ages is required after the ECM parameters are available. Once the OCV estimate is achieved, the SOC estimate is obtained by correlating OCV to SOC on the OCV-SOC curve in the ECM parameter look-up table.

In some embodiments, initial potential Û₀ is determined offline in advance by additional charging simulations. An initial potential estimate Û₀ may be determined as follows. For a specific cell age and temperature, at least one CCCV test may be performed to obtain experimental current and voltage data at selected SOC values ranging from 0-100%. Trying one Û₀ value, a series of initial SOC estimates are calculated at distinct ground truth SOCs (e.g., 5%, 10%, . . . , 95%, or other steps as required by the accuracy and execution time of the machine), assuming that the initial SOC estimation happens at those points. The initial SOC estimate error [symbol] (i.e., the difference between the ground truth SOC and the SOC estimate) may defined by Equation 7 below:

$$= {SOC}_{0} - . \qquad Eq . 7$$

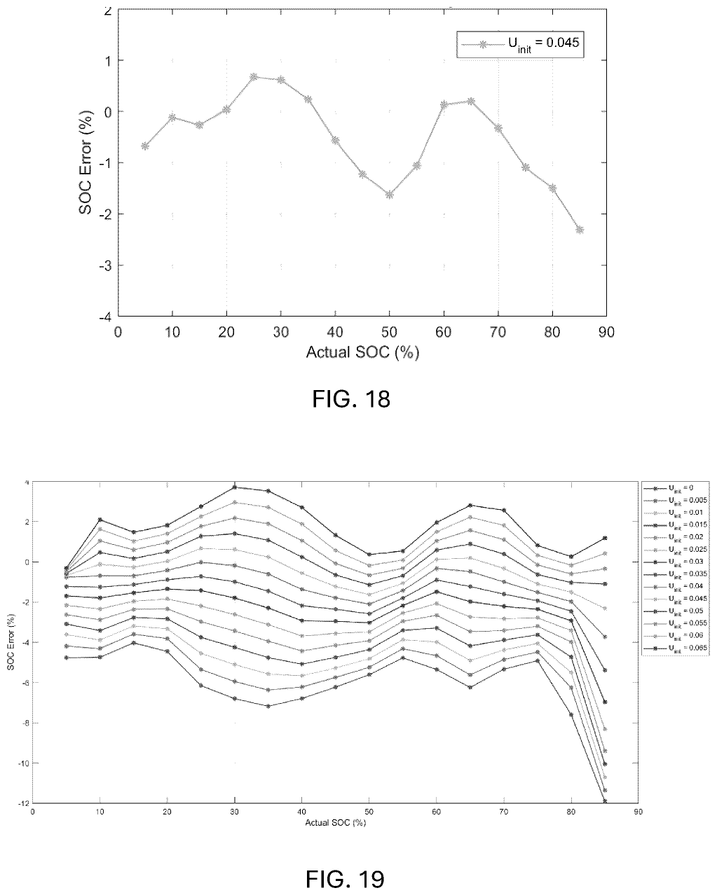

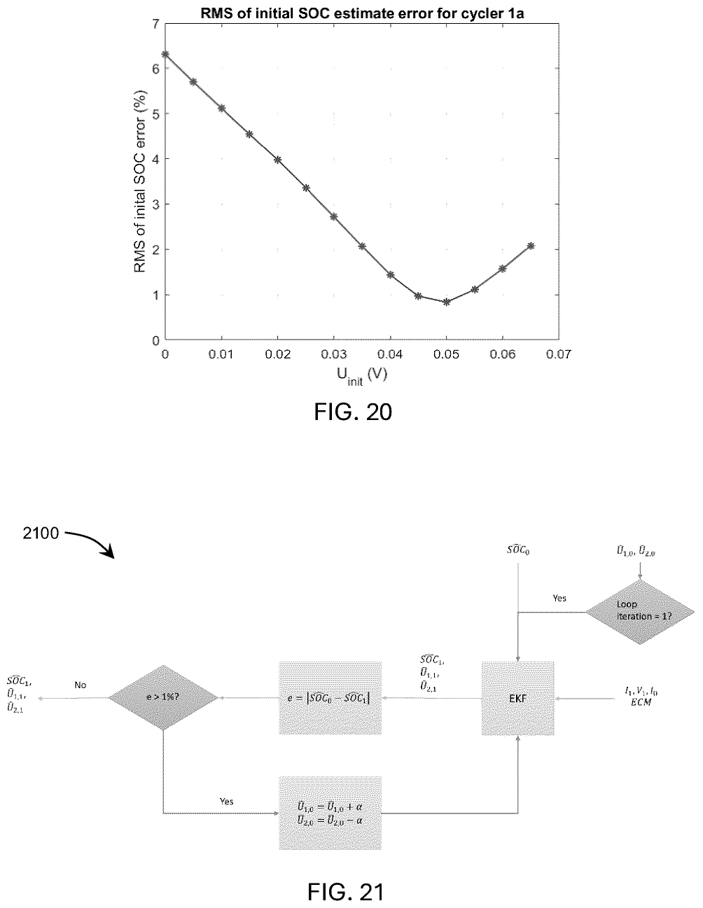

The initial SOC estimate error [symbol] may be calculated at all selected ground truth SOCs, where the tested ground truth SOC value is labeled SOC₀. An example of SOC error versus ground truth (e.g., actual) SOC is shown in FIG. 18. This plot demonstrates the initial SOC estimate error along the tested ground truth SOC under one initial potential estimate Û₀ of 0.045 in this example. Repeating the simulations for several different possible initial potential estimates Û₀ gives a series of initial SOC estimation error curves along the tested ground truth SOCs. An example of this is illustrated in the plot shown in FIG. 19 where several initial potential estimates are tested ranging from 0 to 0.065. One way to evaluate or select one of the tested initial potential estimates Û₀ is to calculate root mean square (RMS) errors for each of the curves. RMS error for each value of initial potential estimate Û₀ is shown in the graph of FIG. 20. Because the goal is to minimize error between the estimated SOC and the actual SOC, the selected initial potential estimate Û₀ value may be the one associated with the smallest RMS value (e.g., 0.05 in the example of FIG. 20). In some embodiments, Û₀ forms a 2-dimensional look-up table along the cell temperatures and the cell ages. It is one input to the proposed EKF-based SOC estimation algorithm module. The initial SOC value [symbol] is saved and is provided to the initial potential adjustment block 1710.

Referring back to FIG. 17, subsequent input information (e.g., current and voltage measurements) is received by the SOC estimation process. This time, the determination at decision block 1706 is “no” and the process moves to a second decision block 1712. At least a portion of the subsequent measurements (e.g., current step voltage Vₖ) is evaluated at block 1712 to determine if it is the second received measurement. If yes, the second current step voltage is provided to the initial potential adjustment block 1710. In addition to receiving second current step voltage and initial SOC estimate [symbol] as an inputs, the initial potential adjustment block 1710 receives or otherwise accesses the initial potential estimate Û₀. Although the summation of the initial potentials (e.g., Û_{1,0} and Û_{2,0}) over the plurality of RC-units can be roughly estimated, the specific value for each potential is still unknown. In fact, an accurate estimation of the initial potentials Û_{1,0} and Û_{2,0} is not required in a standard EKF state estimation procedure discussed with respect to block 1714 in further detail below. However, the quantities of Û_{1,0} and Û_{2,0} do affect the update of [symbol] for the 2^{nd} time step at the initial potential adjustment block 1710. A random choice of Û_{1,0} and Û_{2,0} (e.g., Û1,0=Û₀ and Û_{2,0}=0, or reverse) may lead to a large distance between [symbol] and [symbol] , which may lower the quality of the EKF state estimation. Instead, an algorithm may be used to iteratively adjust the distribution of Û_{1,0} and Û_{2,0} so that the difference between [symbol] and [symbol] can be limited within some pre-defined value or be close as much as possible to that value otherwise.

FIG. 21 shows an algorithm workflow 2100 for determining values for [symbol] , Û_{1,0} and Û_{2,0}. When the 2^{nd} time step of the SOC estimation algorithm (e.g., the workflow illustrated in FIG. 17) starts, the initial SOC estimate [symbol] , along with the initial potential estimates Û_{1,0} and Û_{2,0} are sent to this initial potential adjustment block 1710. In some embodiments, the initial potential estimates Û_{1,0} and Û_{2,0} may be initialized as

$${\hat{U}}_{1 , 0} = {\hat{U}}_{2 , 0} = \frac{1}{2} {\hat{U}}_{0} .$$

Applying the ECM parameters, the 2^{nd} time step inputs I₁, V₁ and the last time step input I₀, a standard EKF procedure can be implemented to obtain the state updates for the current time step: [symbol] , Û_{1,1} and Û_{2,1}. The SOC update error e is defined by Equation 8:

$$e = \vert - \vert . \qquad Eq . 8$$

If e is greater than some pre-defined boundary parameter (e.g., 1% in the example workflow of FIG. 21), an update will be applied to the initial potential estimates according to the Equation Set 9:

$$\{ \begin{matrix}{\hat{U}}_{1 , 0} = {\hat{U}}_{1 , 0} + α \\ {\hat{U}}_{2 , 0} = {\hat{U}}_{2 , 0} - α\end{matrix} . \qquad Eq . 9$$

In Equation Set 9, a is some user-defined initial potential update step; if e does not violate the error update boundary, the algorithm provides the outputs [symbol] , Û_{1,1} and Û_{2,1}. Notably, the design of Equation Set 9 ensures that the summation of Û_{1,0} and Û_{2,0} equals Û₀. In practice, the user may set a limitation to the loop iteration to save computation cost. For example, if the update error e continues to trigger the potential update, the iteration may be stopped when a selected iteration number is reached. In this case, the updated Û_{1,0} and Û_{2,0} corresponding to the minimum e are selected, based on which, the state updates [symbol] , Û_{1,1} and Û_{2,1} will be determined after one additional EKF estimation procedure.

Referring back to FIG. 17, the initial potential adjustment block 1710 provides as outputs first and second initial potentials Û_{1,1} and Û_{2,1} associated with the first and second RC units of the ECM discussed with respect to FIG. 13. The initial potential adjustment block 1710 generates updated estimated cell dynamics states (e.g., updated SOC estimate [symbol] and updated potential estimates Û_{1,1}, Û_{2,1}) by using an EKF procedure. The three estimated states [symbol] , Û_{1,1}, and Û_{2,1} output from the initial potential adjustment block 1710 may be used for further EKF procedures. The initial [symbol] estimate may also be a stand-alone output of the SOC estimation process.

Beginning with the third received voltage measurement (e.g., where decision blocks 1706 and 1712 are both answered “no”), feedback measurements are directed to an EKF module 1714. EKF module inputs include Iₖ, Vₖ, Iₖ₋₁ and the last-time-step-state-estimate (e.g., as denoted by the k−1 subscript) [symbol] , Û_{1,k-1}, Û_{2,k-1} for k≥2. The EKF module 1714 then updates the state estimates [symbol] , Û_{1,k}, Û_{2,k} for the current time step. At each time step k, the EKF module outputs the SOC estimate [symbol] . The EKF module continues to operate until internal states of the EKF converge.

The EKF procedure may be a standard EKF process. The EKF process may use the current time step inputs Iₖ, Vₖ, the last time step current input Iₖ₋₁ and the last time step state estimates [symbol] , Û_{1,k-1}, Û_{2,k-1}. After one or more iterations, the EKF generates and provides as outputs the updated state estimates [symbol] , Û_{1,k}, Û_{2,k} for the current time step. An important step in the EKF algorithm is the state prediction, which takes advantage of the last state estimates and the cell dynamics model of Equations 3-4B and predicts the states for the current time step without estimation trust weighing. This procedure, along with the final state estimation weighing, is the fundamental frame of the EKF and can be simply expressed by Equation Set 10:

$$\{ \begin{matrix}{\hat{x}}_{k \vert k - 1} = f ( {\hat{x}}_{k - 1 \vert k - 1} , {I}_{k - 1} ) \\ {\hat{x}}_{k \vert k} = {\hat{x}}_{k \vert k - 1} + {K}_{k} ( {V}_{k} - {\hat{V}}_{k \vert k - 1} )\end{matrix} . \qquad Eq . 10$$

In Equation Set 10, \hat{x}_{k-1|k-1}=[ [symbol] U_{1,k-1} Û_{2,k-1}]^{T} is the state estimate for the last time step, \hat{x}_{k|k-1}=[ [symbol] Û_{1,k|k-1} Û_{2,k|k-1}]^{T} is the state prediction based on the information of the last time step state estimates, \hat{x}_{k|k} is the state estimate for the current time step, and KK is the Kalman gain for the current time step. \hat{V}_{k|k-1} is the predicted voltage output simply based on the information of the last time step, which may be calculated using Equation 11:

$${\hat{V}}_{k \vert k - 1} = OCV ( ) + {R}_{0} ( ) {I}_{k} + {\hat{U}}_{1 , k \vert k - 1} + {\hat{U}}_{2 , k \vert k - 1} \qquad Eq . 11$$

and the nonlinear function of Equation 12:

$$f = [ \begin{matrix}+ \frac{{τ}_{s}}{{Q}_{cell}} {I}_{k - 1} \\ {e}^{- \frac{{T}_{s}}{{τ}_{1} ( )}} {\hat{U}}_{1 , k \vert k - 1} + ( 1 - {e}^{- \frac{{T}_{s}}{{τ}_{1} ( )}} ) {R}_{1} ( ) {I}_{k - 1} \\ {e}^{- \frac{{T}_{s}}{{τ}_{2} ( )}} {\hat{U}}_{2 , k \vert k - 1} + ( 1 - {e}^{- \frac{{T}_{s}}{{τ}_{2} ( )}} ) {R}_{2} ( ) {I}_{k - 1}\end{matrix} ] . \qquad Eq . 12$$

Equations 11 and 12 represent the dynamics of Equations 3-4B except that all states are replaced by the predicted states. While these equations are able to provide a predicted voltage output \hat{V}_{k|k-1}, other means for obtaining a predicted voltage output may be used. For example, statistical models or neural networks may be used instead of or in addition to the equations to achieve similar results.

The standard EKF procedure may not be applied to the end of charging/discharging. Instead, this algorithm can be terminated at some point to save computation costs for more practical implementations. In some embodiments, the standard EKF algorithm ends when the predicted SOC [symbol] converges and approaches within a selected error threshold of the SOC estimate [symbol] at some time step k. Since [symbol] is an internal state of the EKF, the procedure is also referred to as the internal state convergency. To clarify the idea, an SOC prediction error may be defined according to Equation 13:

$${e}_{p} = \vert - \vert . \qquad Eq . 13$$

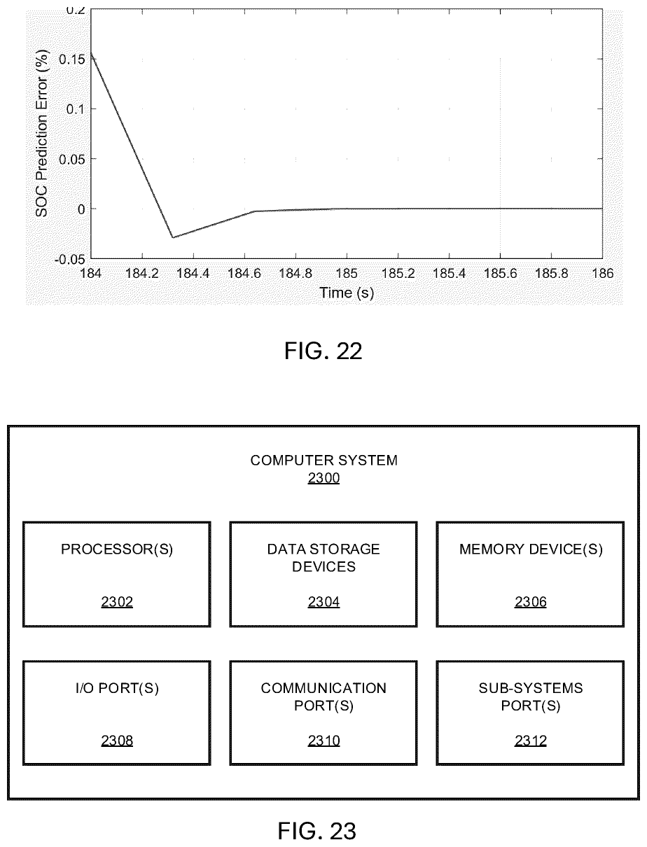

Therefore, the EKF iterative procedure can be terminated once eₚ≤λ, where λ>0 is a user-defined constant parameter. One example of this procedure can be viewed in FIG. 22. FIG. 22 illustrates an iterative EKF process occurring over time where convergence of the internal state is observed after only a few iterations.

In some embodiments, the degree to which to states converge may be a selected or predetermined threshold. Referring back to FIG. 17, the degree of convergence may be evaluated in a third decision block 1716. If the convergence is sufficient, a current time step SOC estimate SOCK may be output from the EKF module. In some embodiments, the EKF module may continue to run as additional feedback signals are received and subsequent updated current time step SOCK estimates may be provided. However, to reduce demand on processing and other resources in the system, some embodiments may optionally include the use of a coulomb counting module 1718. In such embodiments, a current time step SOC estimate SOCK may be output from the EKF module and provided to the coulomb counting module 1718. The coulomb counting module may then take over updating the current time step SOC estimate SOCK as additional feedback signals are received. Using a coulomb counting approach to update a current time step SOC estimate based on the estimate received from the EKF module may provide reliable estimates while minimizing processing and resource demand. Coulomb counting module 1718 calculates an SOC estimate based on an accumulation of charge. In some embodiments, Equation 14 is used to calculate the current time step SOC estimate:

$$= + \frac{{T}_{s}}{{Q}_{c e l l}} {I}_{k - 1} . \qquad Eq . 14$$

Coulomb counting module outputs the current time step SOC estimate [symbol] .

Referring to FIG. 23, a block diagram of an example computer system 2300 is shown, where the computer system 2300 includes one or more computing units that may implement various systems and methods discussed herein. The computer system 2300 may be part of a controller, may be in operable communication with various implementation discussed herein, may run various operations related to the method discussed herein, may run offline to process various data for characterizing a battery, and may be part of overall systems discussed herein. The computer system 2300 may process various signals discussed herein and/or may provide various signals discussed herein. For example, battery measurement information may be provided to such a computer system 2300. The computer system 2300 may also be applicable to, for example, the controller, the model, the tuning/shaping circuits discussed with respect to the various figures and may be used to implement the various methods described herein. It will be appreciated that specific implementations of these devices may be of differing possible specific computing architectures, not all of which are specifically discussed herein but will be understood by those of ordinary skill in the art. It will further be appreciated that the computer system may be considered and/or include an ASIC, FPGA, microcontroller, or other computing arrangement. In such various possible implementations, more or fewer components discussed below may be included, interconnections and other changes made, as will be understood by those of ordinary skill in the art.

The computer system 2300 may be a computing system that may execute a computer program product to execute a computer process. Data and program files may be input to the computer system 2300, which reads the files and executes the programs therein. Some of the elements of the computer system 2300 are shown in FIG. 23, including one or more hardware processors 2302, one or more data storage devices 2304, one or more memory devices 2306, and/or one or more ports 2308-2312. Additionally, other elements that will be recognized by those skilled in the art may be included in the computer system 2300 but are not explicitly depicted in FIG. 23 or discussed further herein. Various elements of the computer system 2300 may communicate with one another by way of one or more communication buses, point-to-point communication paths, or other communication means not explicitly depicted in FIG. 23. Similarly, in various implementations, various elements disclosed in the system may or not be included in any given implementation.

The processor 2302 may include, for example, a central processing unit (CPU), a microprocessor, a microcontroller, a digital signal processor (DSP), and/or one or more internal levels of cache. The processor 2302 may include a memory for permanent or temporary storage. There may be one or more processors 2302, such that the processor 2302 comprises a single central-processing unit, or a plurality of processing units capable of executing instructions and performing operations in parallel with each other, commonly referred to as a parallel processing environment.

The presently described technology in various possible combinations may be implemented, at least in part, in software stored on the data stored device(s) 2304, stored on the memory device(s) 2306, and/or communicated via one or more of the ports 2308-2312, thereby transforming the computer system 2300 in FIG. 23 to a special purpose machine for implementing the operations described herein.

The one or more data storage devices 2304 may include any non-volatile data storage device capable of storing data generated or employed within the computer system 2300, such as computer executable instructions for performing a computer process, which may include instructions of both application programs and an operating system (OS) that manages the various components of the computer system 2300. The data storage devices 2304 may include, without limitation, magnetic disk drives, optical disk drives, solid state drives (SSDs), flash drives, and the like. The data storage devices 2304 may include removable data storage media, non-removable data storage media, and/or external storage devices made available via a wired or wireless network architecture with such computer program products, including one or more database management products, web server products, application server products, and/or other additional software components. Examples of non-removable data storage media include internal magnetic hard disks, SSDs, and the like. The one or more memory devices 2306 may include volatile memory (e.g., dynamic random-access memory (DRAM), static random-access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 2304 and/or the memory devices 2306, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computer system 2300 includes one or more ports, such as an input/output (I/O) port 2308, a communication port 2310, and a sub-systems port 2312, for communicating with other computing, network, or vehicle devices. It will be appreciated that the ports 2308-2312 may be combined or separate and that more or fewer ports may be included in the computer system 2300. The I/O port 2308 may be connected to an I/O device, or other device, by which information is input to or output from the computing system 2300. Such I/O devices may include, without limitation, one or more input devices, output devices, and/or environment transducer devices. In some embodiments, the computer system 2300 includes peripherals and I/O ports to measure signals (e.g., voltage and current) and provide controls for a stimulus to a battery cell.

In one implementation, the input devices convert a human-generated signal, such as, human voice, physical movement, physical touch or pressure, and/or the like, into electrical signals as input data into the computing system 2300 via the I/O port 2308. In some examples, such inputs may be distinct from the various system and method discussed with regard to the preceding figures. Similarly, the output devices may convert electrical signals received from computer system 2300 via the I/O port 2308 into signals that may be sensed or used by the various methods and system discussed herein. The input device may be an alphanumeric input device, including alphanumeric and other keys for communicating information and/or command selections to the processor 2302 via the I/O port 2308.

The environment transducer devices convert one form of energy or signal into another for input into or output from the computer system 2300 via the I/O port 2308. For example, an electrical signal generated within the computing system 2300 may be converted to another type of signal, and/or vice-versa. In one implementation, the environment transducer devices sense characteristics or aspects of an environment local to or remote from the computer device 2300, such as battery voltage, open circuit battery voltage, charge current, battery temperature, light, sound, temperature, pressure, magnetic field, electric field, chemical properties, and/or the like.

In one implementation, a communication port 2310 may be connected to a network by way of which the computer system 2300 may receive network data useful in executing the methods and systems set out herein as well as transmitting information and network configuration changes determined thereby. For example, charging protocols may be updated, battery measurement or calculation data shared with external system, and the like. The communication port 2310 connects the computer system 2300 to one or more communication interface devices configured to transmit and/or receive information between the computer system 2300 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 2310 to communicate with one or more other machines, either directly over a point-to-point communication path, over a wide area network (WAN) (e.g., the Internet), over a local area network (LAN), over a cellular (e.g., third generation (3G), fourth generation (4G), fifth generation (5G)) network, or over another communication means.

The computer system 2300 may include a sub-systems port 2312 for communicating with one or more systems related to a device being charged according to the methods and system described herein to control an operation of the same and/or exchange information between the computer system 2300 and one or more sub-systems of the device. Examples of such sub-systems of a vehicle, include, without limitation, motor controllers and systems, battery control systems, and others.

The system set forth in FIG. 23 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

Embodiments of the present disclosure include various steps, which are described in this specification. The steps may be performed by hardware components or may be embodied in machine-executable instructions, which may be used to cause a general-purpose or special-purpose processor programmed with the instructions to perform the steps. Alternatively, the steps may be performed by a combination of hardware, software and/or firmware.

Various modifications and additions can be made to the exemplary embodiments discussed without departing from the scope of the present invention. For example, while the embodiments, also referred to as implementations or examples, described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and, such references mean at least one of the embodiments.

Reference to “one embodiment” or “an embodiment” means that a particular feature, structure, or characteristic described in connection with the embodiment is included in at least one embodiment of the disclosure. The appearances of the phrase “in one embodiment”, or similarly “in one example” or “in one instance”, in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims or can be learned by the practice of the principles set forth herein.

What is claimed is:

1. A method of generating a State of Health (SOH) estimate for a battery, the method comprising:
charging a battery cell to a reference point;
obtaining a battery cell temperature at the reference point;
obtaining an instantaneous impedance of the battery cell based on a response of the battery cell to an applied probing waveform;
obtaining a SOH estimate based on the battery cell temperature and the instantaneous impedance.

2. The method of claim 1, wherein obtaining the SOH estimate comprises:
providing the battery cell temperature and the instantaneous impedance as inputs to a SOH look-up table; and
receiving the SOH estimate from the SOH look-up table.

3. The method of claim 1, wherein obtaining the SOH estimate comprises:
providing the battery cell temperature and the instantaneous impedance as inputs to at least one selected from a group consisting of a statistical model, an equation, and a neural network; and
receiving the SOH estimate from the at least one selected from the group consisting of the statistical model, the equation, and the neural network.

4. The method of claim 1, further comprising obtaining an End of Life (EOL) estimate based on the battery cell temperature and the instantaneous impedance.

5. The method of claim 4, wherein obtaining the EOL estimate comprises:
providing the battery cell temperature and the instantaneous impedance as inputs to an EOL look-up table; and
determining the EOL estimate.

6. The method of claim 4, wherein obtaining the EOL estimate comprises:
providing the battery cell temperature and the instantaneous impedance as inputs to a EOL model; and
determining the EOL estimate.

7. The method of claim 4, wherein the EOL estimate comprises a number of cycles remaining.

8. The method of claim 4, wherein the EOL estimate comprises a percent of rated capacity remaining.

9. The method of claim 1, wherein the applied probing waveform is a unipolar pulse probing waveform characterized by a duration and a charge rate magnitude.

10. The method of claim 9, wherein the duration is between approximately 1 second and approximately 10 minutes.

11. The method of claim 9, wherein the charge rate magnitude is between approximately 0.1 C and approximately 5 C.

12. The method of claim 1, wherein the reference point is defined by an open-circuit voltage (OCV) value.

13. The method of claim 1, wherein the reference point is approximately 20% to approximately 80% of a nominal voltage range of the battery cell.

14. A method of generating a State of Charge (SOC) estimate, the method comprising:
receiving, at an initial SOC estimate module, a first time step voltage measurement, a first time step current measurement, and an equivalent circuit model (ECM);
performing, using the first time step voltage measurement, the first time step current measurement, and the ECM, an initial SOC estimation process to obtain an initial SOC estimate;
providing the initial SOC estimate and a second time step voltage measurement to an initial potential adjustment module;
performing, using the initial SOC estimate and the second time step voltage measurement, an initial potential adjustment process to obtain at least one state estimate, wherein the at least one state estimate comprises an updated initial SOC estimate;
providing the at least one state estimate, a second time step current measurement, and a third time step voltage measurement to an extended Kalman filter (EKF) module; and
performing, using the at least one state estimate, the second time step current measurement, and the third time step voltage measurement, an EKF process to obtain a current time step SOC estimate.

15. The method of claim 14, wherein the ECM comprises an ECM parameter model.

16. The method of claim 15, wherein the ECM parameter model comprises a look-up table.

17. The method of claim 15, wherein the ECM parameter model comprises ECM parameter data as a function of SOC, temperature, and battery cell age.

18. The method of claim 14, wherein the initial SOC estimation process comprises:
calculating an open circuit voltage (OCV); and
correlating the OCV to the initial SOC estimate using a OCV-SOC curve in the ECM parameter model.

19. The method of claim 14, wherein the ECM parameter model further comprises an initial potential summation estimate.

20. The method of claim 19, wherein the initial potential summation estimate is determined using a testing process comprising:
performing a constant current constant voltage (CCCV) test over a SOC range to determine known SOC values;
testing a plurality of initial potential summation estimate values by generating a series of associated estimated SOC values for each of the plurality of initial potential summation estimate values;
calculating a SOC error between estimated SOC values and known SOC values for each of the plurality of initial potential summation estimate values; and
selecting the initial potential summation estimate value associated with the smallest SOC error.

21. The method of claim 20, wherein the SOC range is from approximately 0% SOC to approximately 100% SOC.

22. The method of claim 20, wherein calculating the SOC error comprises calculating a root-mean-square (RMS) error.

23. The method of claim 20, wherein the EKF process further comprises determining a first initial potential value and a second initial potential value based at least in part on the selected summation of initial potentials value.

24. The method of claim 20, further comprising stopping iterating of the EKF process when the current time step SOC estimate converges.

25. The method of claim 24, wherein convergence of the current time step SOC estimate is achieved when the difference between a prior time step SOC estimate and the current time step SOC estimate is less than a threshold.

26. The method of claim 20, further comprising stopping iterating of the EKF process when a threshold number of iterations is met.

27. The method of claim 14, further comprising:
providing the current time step SOC estimate to a coulomb counting module; and
calculating a coulomb counting-based SOC estimate based at least in part on the current time step SOC estimate, the current time step current measurement, a battery cell capacity, and temperature.

28. A method of determining amount of remaining device use comprising:
obtaining a SOH estimate for a battery within a device;
obtaining a SOC estimate for the battery within the device;
obtaining an amount of energy discharge required to use the device; and
determining the amount of remaining device use available for the battery's SOH, SOC and amount of energy discharge required.

29. The method of claim 28, wherein the amount of energy discharge comprises an instantaneous energy discharge.

30. The method of claim 28, wherein the amount of energy discharge comprises an average energy discharge.

31. The method of claim 28, wherein determining the amount of remaining device use available comprises determining an amount of use time remaining.

32. The method of claim 28, wherein determining the amount of remaining device use available comprises determining a number of discrete task completions remaining.
